(19) United States
(12) Patent Application Publication
(10) Pub. No.: US 2025/0374573 A1
(43) Pub. Date: Dec. 4, 2025

(54) SEMICONDUCTOR DEVICE

(71) Applicant: Mitsubishi Electric Corporation, Tokyo (JP)

(72) Inventors: Kosuke SAKAGUCHI, Tokyo (JP); Kazuya KONISHI, Tokyo (JP)

(73) Assignee: Mitsubishi Electric Corporation, Tokyo (JP)

(21) Appl. No.: 19/071,721

(22) Filed: Mar. 5, 2025

(30) Foreign Application Priority Data
May 29, 2024 (JP) 2024-087043

(51) Int. Cl. H10D 12/00; H10D 62/10; H10D 62/60; H10D 64/27

(52) U.S. Cl. CPC H10D 12/481; H10D 62/125; H10D 62/60; H10D 64/513; H10D 64/518

(57) ABSTRACT

An object of the present disclosure is to suppress displacement current in a semiconductor device having a two-stage gate structure and a carrier storage layer. An IGBT includes a carrier storage layer of a first conductivity type, a base layer of a second conductivity type formed on a side of the first main surface of the carrier storage layer, and a gate electrode buried in a trench. The gate electrode includes a lower stage gate electrode and an upper stage gate electrode. In the carrier storage layer, an impurity concentration of a first conductivity has a gauss distribution in a depth direction, and a depth D1 of an interface between the base layer and the carrier storage layer near a sidewall of the trench satisfies D1≥(D2−1.0) [μm] with respect to a depth D2 of a deepest part of the upper stage gate electrode.

### BACKGROUND

### Technical Field

The present disclosure relates to a semiconductor device.

### Description of the Background Art

Conventionally, there is a problem in an insulated gate bipolar transistor (IGBT) structure including a carrier storage layer (CS layer) that displacement current flows in a trench gate during a switching operation or a short-circuit state, overshoot occurs in gate-emitter voltage, and overcurrent flows.

In order to deal with such a problem, Japanese Patent Application Laid-Open No. 2023-116894 discloses a structure that a two-stage gate structure having gate potential in an upper stage and emitter potential in a lower stage is adopted to suppress the displacement current.

### SUMMARY

However, there is a problem that the displacement current is not sufficiently suppressed only by adopting the two-stage gate structure. Not only the IGBT but also the other semiconductor device including a carrier storage layer such as a MOSFET has a similar problem.

An object of the present disclosure is to suppress displacement current in a semiconductor device having a two-stage gate structure and a carrier storage layer.

A semiconductor device according to the present disclosure includes a semiconductor substrate, a drift layer of a first conductivity type, a carrier storage layer of a first conductivity type, a base layer of a second conductivity type, a trench, and a gate electrode. The semiconductor substrate includes a first main surface and a second main surface as a main surface on a side opposite to the first main surface. The drift layer is formed on the semiconductor substrate. The carrier storage layer is formed on a side of the first main surface of the drift layer. The base layer is formed on a side of the first main surface of the carrier storage layer. The trench passes through the base layer and the carrier storage layer from the first main surface to reach the drift layer. The gate electrode is buried in the trench via an oxide film. The gate electrode includes a lower stage gate electrode and an upper stage gate electrode. The upper stage gate electrode is formed closer to the side of the first main surface than the lower stage gate electrode. In the carrier storage layer, an impurity concentration of a first conductivity type has a gauss distribution in a depth direction. A depth D1 of an interface between the base layer and the carrier storage layer near a sidewall of the trench satisfies D1≥(D2−1.0) [μm] with respect to a depth D2 of a deepest part of the upper stage gate electrode.

In the semiconductor device according to the present disclosure, the depth D1 of the interface between the base layer and the carrier storage layer near the sidewall of the trench satisfies D1≥(D2−1.0) [μm] with respect to the depth D2 of the deepest part of the upper stage gate electrode; thus, a thickness of a region where the carrier storage layer and the upper stage gate electrode are overlapped with each other gets small. Since the displacement current hardly flows in the upper stage gate electrode, overcurrent is suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating a semiconductor device according to an embodiment 1.

FIG. 2 is a diagram illustrating a relationship between a boron drive time and a displacement current charge amount.

FIG. 3 is a cross-sectional view illustrating a semiconductor device according to an embodiment 2.

FIG. 4 is a cross-sectional view illustrating the semiconductor device according to the embodiment 2.

### DESCRIPTION OF THE PREFERRED EMBODIMENTS

In the description hereinafter, an N type is a first conductivity type, and a P type is a second conductivity type in a conductivity type of semiconductor. However, these may be inverted. That is to say, the N type may be the second conductivity type, and the P type may be the first conductivity type.

### A. Embodiment 1

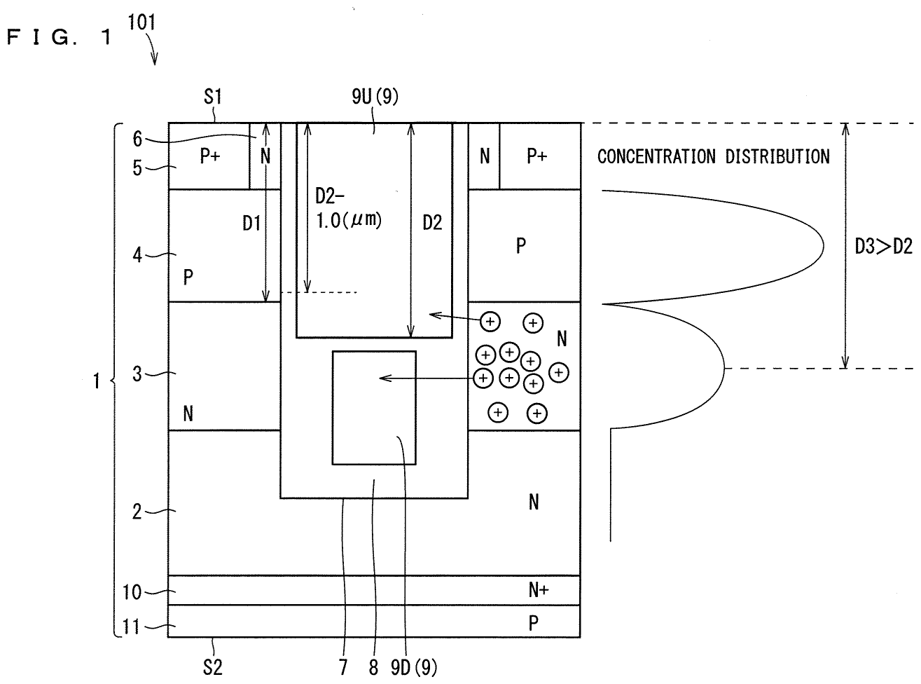

FIG. 1 is a cross-sectional view illustrating a configuration of an IGBT 101 as a semiconductor device according to an embodiment 1. The IGBT 101 includes a semiconductor substrate 1. The semiconductor substrate 1 includes a first main surface S1 and a second main surface S2 as a main surface on a side opposite to the first main surface S1. In FIG. 1, the first main surface S1 is an upper main surface, and the second main surface S2 is a lower main surface.

The semiconductor substrate 1 includes an N-type drift layer 2. An N-type carrier storage layer (CS layer) 3 is provided on a side of the first main surface S1 of the N-type drift layer 2. A P-type base layer 4 is provided on the side of the first main surface S1 of the CS layer 3. A P+-type contact layer 5 and an N-type source layer 6 are provided on the side of the first main surface S1 of the base layer 4. Surfaces of the contact layer 5 and the source layer 6 on a side opposite to the base layer 4, that is to say, upper surfaces thereof constitute the first main surface S1. Although not shown in the diagrams, an emitter electrode as a front surface electrode is formed in the first main surface S1.

An N+-type buffer layer 10 is provided to a side of the second main surface S2 of the drift layer 2. A P-type collector layer 11 is provided to the side of the second main surface S2 of the buffer layer 10. A surface of the collector layer 11 on a side opposite to the buffer layer 10, that is to say, a lower surface of the collector layer 11 in FIG. 1 constitutes the second main surface S2. Although not shown in the diagrams, a collector electrode as a back surface electrode is provided on the second main surface S2.

Formed is a trench 7 passing through the source layer 6, the base layer 4, and the CS layer 3 from the first main surface S1 to reach the drift layer 2. A gate electrode 9 is buried in the trench 7 via an oxide film 8. The gate electrode 9 includes a lower stage gate electrode 9D and an upper stage gate electrode 9U located on an upper side than the lower stage gate electrode 9D, that is to say, on the side of the first main surface S1. That is to say, the IGBT 101 has a two-stage gate structure. The lower stage gate electrode 9D and the upper stage gate electrode 9U are insulated from each other by the oxide film 8.

Hole carriers from the second main surface S2 are easily stored in the drift layer 2 by the CS layer 3. Accordingly, conductivity modulation easily occurs, and power conduction loss is reduced. Although the IGBT is described in the present embodiment, the configuration according to the present disclosure can also be adopted to a metal oxide semiconductor field effect transistor (MOSFET) which does not include the collector layer 11.

The IGBT 101 has a two-stage gate structure including two-stage gate electrodes of a lower stage gate electrode 9D and an upper stage gate electrode 9U. A depth of an interface between the CS layer 3 and the base layer 4 near a sidewall of the trench 7 (simply referred to as “near the trench 7” hereinafter) is D1, and a depth of a deepest part of the upper stage gate electrode 9U is D2. The interface between the CS layer 3 and the base layer 4 is also referred to as the CD/CS interface hereinafter. At this time, D1≤D2 needs to be satisfied. The reason is that when D1>D2 is satisfied, a part of the base layer 4 on a side of the CS layer 3 near the trench 7 does not face the upper stage gate electrode 9U; thus, the type of the base layer 4 is not inverted to the n type, and ON current does not flow. Unless otherwise described, a depth of each part in the present specification is a depth from the first main surface S1.

Although the CS layer 3 needs to face the upper stage gate electrode 9U, a thickness of the facing part is preferably as small as possible. Specifically, D1≥(D2−1.0) [μm] is preferably satisfied. In other words, a thickness of the CS layer 3 facing the upper stage gate electrode 9U is preferably equal to or larger than 1.0 [μm].

In this manner, when the thickness of the region where the CS layer 3 and the upper stage gate electrode 9U are overlapped with each other is reduced, the displacement current hardly flows in the upper stage gate electrode 9U, thus, overcurrent is suppressed.

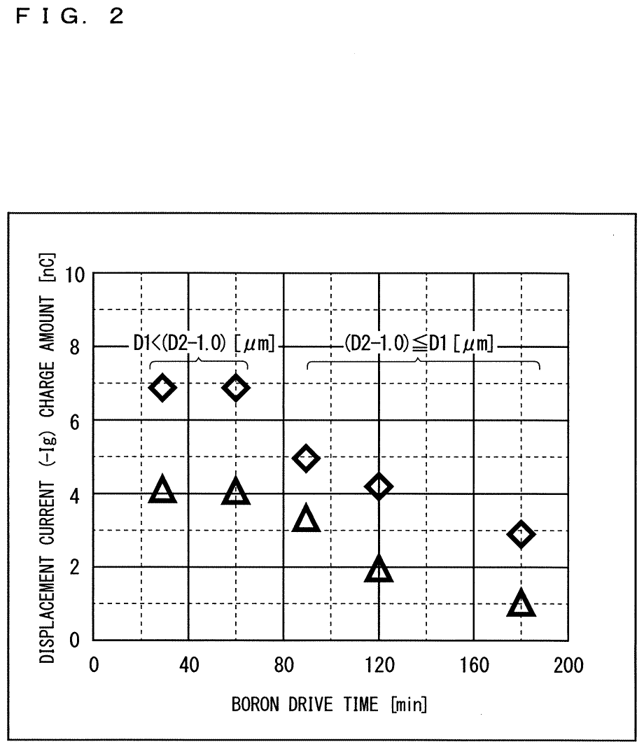

FIG. 2 illustrates a relationship between a boron drive time [min] and a displacement current charge amount [nC]. The boron drive time is a heat processing time in forming the base layer 4. In accordance with this heat processing, implanted boron as a p-type impurity is diffused, and the base layer 4 is formed. Accordingly, the depth of the CD/CS interface gets larger as the boron drive time increases.

A triangle mark indicates a case where an n-type impurity concentration of the CS layer 3 is 3.0×10¹² [cm-3], and a rhomboid mark indicates a case where an n-type impurity concentration of the CS layer 3 is 6.0×10¹² [cm-3]. A state where the boron drive time is 30 [min] and 60 [min] corresponds to a case where the depth D1 of the CD/CS interface is smaller than (D2−1.0) [μm]. A state where the boron drive time is 90 [min], 12 [min], and 180 [min] corresponds to a case where the depth D1 of the CD/CS interface is equal to or larger than (D2−1.0) [μm]. FIG. 2 shows that when D1≥(D2−1.0) [μm] is satisfied, the displacement current charge amount gets small, that is to say, the displace current decreases.

As illustrated in FIG. 1, a distribution of an n-type impurity in the CS layer 3 in the IGBT 101 in a depth direction is preferably a gauss distribution. When a depth of a peak position of the n-type impurity concentration in the CS layer 3 is D3, D2<D3 is preferably satisfied. Accordingly, holes in the peak position in the CS layer 3 as a region where the holes are stored most easily can be pulled from the lower stage gate electrode 9D, and the displacement current flowing in the upper stage gate electrode 9U is further suppressed.

It is preferable that the lower stage gate electrode 9D has the same potential as the emitter electrode, that is to say, emitter potential, and the upper stage gate electrode 9U has gate potential different from the emitter potential. Accordingly, the holes flowing in the lower stage gate electrode 9D can be transferred to the emitter electrode.

The n-type impurity concentration of the lower stage gate electrode 9D is preferably higher than the n-type impurity concentration of the upper stage gate electrode 9U. Accordingly, parasitic resistance of the lower stage gate electrode 9D decreases, and the displacement current flowing in the upper stage gate electrode 9U is suppressed.

As described above, the IGBT 101 as the semiconductor device according to the embodiment 1 includes the semiconductor substrate 1, the n-type drift layer 2, the n-type CS layer 3, the p-type base layer 4, the trench 7, and the gate electrode 9. The semiconductor substrate 1 includes the first main surface S1 and the second main surface S2 as the main surface on the side opposite to the first main surface S1. The drift layer 2 is formed on the semiconductor substrate 1. The CS layer 3 is formed on the side of the first main surface S1 of the drift layer 2. The base layer 4 is formed on the side of the first main surface S1 of the CS layer 3. The trench 7 passes through the base layer 4 and the CS layer 3 from the first main surface S1 to reach the drift layer 2. The gate electrode 9 is buried in the trench 7 via the oxide film 8. The gate electrode 9 includes the lower stage gate electrode 9D and the upper stage gate electrode 9U formed closer to the side of the first main surface S1 than the lower stage gate electrode 9D. In the CS layer 3, the impurity concentration of the first conductivity type has the gauss distribution in the depth direction. The depth D1 of the CD/CS interface near the sidewall of the trench 7 satisfies D1≥(D2−1.0) [μm] with respect to the depth D2 of the deepest part of the upper stage gate electrode 9U.

In this manner, when the thickness of the region where the CS layer 3 and the upper stage gate electrode 9U are overlapped with each other is reduced, the displacement current hardly flows in the upper stage gate electrode 9U, thus, overcurrent is suppressed.

### B. Embodiment 2

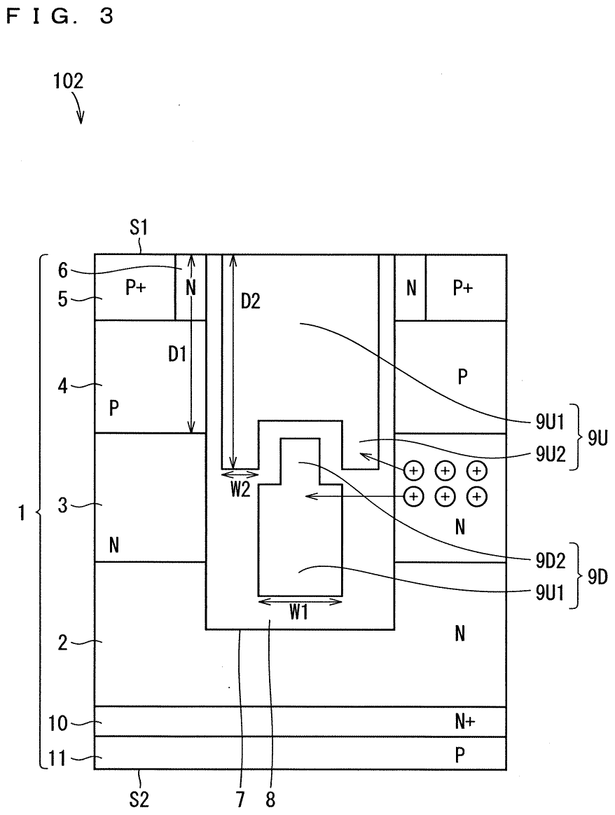

FIG. 3 is a cross-sectional view illustrating a configuration of an IGBT 102 as a semiconductor device according to an embodiment 2. Shapes of the upper stage gate electrode 9U and the lower stage gate electrode 9D in the IGBT 102 are different from those in the IGBT 101. The shapes of the upper stage gate electrode 9U and the lower stage gate electrode 9D according to the embodiment 2 are described hereinafter.

The upper stage gate electrode 9U includes an upper stage first part 9U1 and an upper stage second part 9U2 protruding to a side of the second main surface S2 from a lower surface of the upper stage first part 9U1 on the side of the second main surface S2, and has a concave shape toward the second main surface S2. A lower surface of the upper stage second part 9U2 is a deepest part of the upper stage gate electrode 9U, and a depth thereof is D2.

The lower stage gate electrode 9D includes a lower stage first part 9D1 and a lower stage second part 9D2 protruding to a side of the first main surface S1 from an upper surface of the lower stage first part 9D1 on the side of the first main surface S1, and has a convex shape toward the first main surface S1.

All the other features described in the embodiment 1 are also applied to the embodiment 2.

Since the upper stage gate electrode 9U has the downward concave shape, a volume of the upper stage gate electrode 9U decreases. Resistance of an inlet of the holes in the upper stage gate electrode 9U increases. Accordingly, the displacement current flowing in the upper stage gate electrode 9U is suppressed.

Since the lower stage gate electrode 9D has the upward convex shape, a volume of the lower stage gate electrode 9D increases. Accordingly, parasitic resistance of the lower stage gate electrode decreases, and the displacement current flowing in the upper stage gate electrode 9U is suppressed.

The convex part of the upper stage gate electrode 9U may be fitted into the concave part of the lower stage gate electrode 9D. That is to say, the upper surface of the lower stage second part 9D2 may be shallower than a bottom surface of the upper stage second part 9U2. Accordingly, a volume of the lower stage gate electrode 9D increases. As a result, parasitic resistance of the lower stage gate electrode decreases, and the displacement current flowing in the upper stage gate electrode 9U is suppressed.

A width W2 of the upper stage second part 9U2 may be smaller than a width W1 of the lower stage first part 9D1. Accordingly, a cross-sectional area of the upper stage second part 9U2 decreases, and the parasitic resistance increases. As a result, the displacement current flowing in the upper stage gate electrode 9U is suppressed.

One of the upper stage gate electrode 9U and the lower stage gate electrode 9D may have the same configuration as that in the embodiment 1.

### C. Embodiment 3

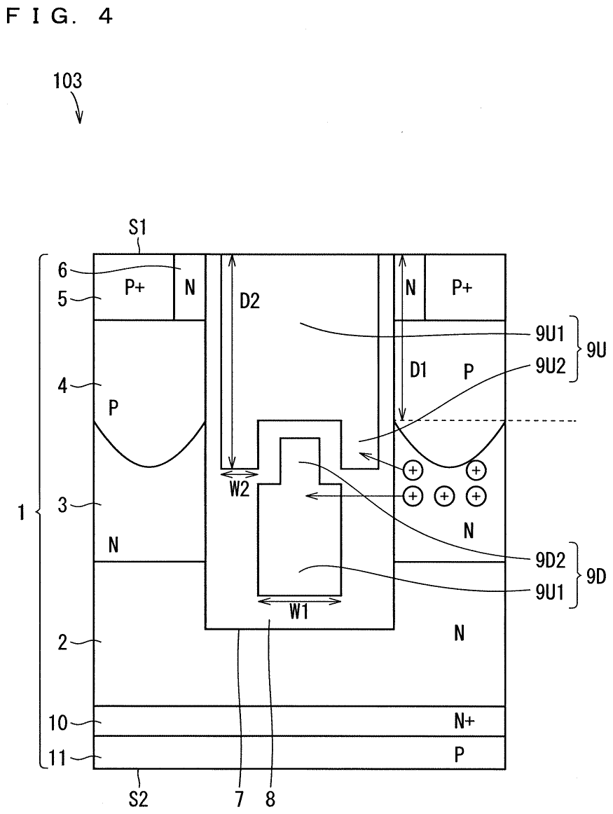

FIG. 4 is a cross-sectional view illustrating a configuration of an IGBT 103 as a semiconductor device according to an embodiment 3. The IGBT 103 is different from the IGBT 102 according to the embodiment 2 in that a depth of the CD/CS interface is not flat.

In the IGBT 103, the CD/CS interface is shallow near the trench 7, and gets deeper as increasing distance from the trench 7, thus has a convex shape toward the first main surface S1. That is to say, the depth of the CD/CS interface is D1 near the trench 7, and is larger than D1 at a position away from the trench 7. Accordingly, the base layer 4 in a mesa center part is thickened. As a result, carrier storage is suppressed near the upper stage gate electrode 9U, and the displacement current flowing in the upper stage gate electrode 9U is further suppressed.

Features regarding the depths D1, D2, and D3 of each part described in the embodiment 1 are also applied to those in the embodiment 3 in the similar manner. Described in FIG. 4 is a configuration that the IGBT 103 is similar to the IGBT 102 in the embodiment 2 except that the CD/CS interface is convex downward. However, also applicable is a configuration that the IGBT 103 is similar to the IGBT 101 in the embodiment 1 except that the CD/CS interface is convex downward.

When the base layer 4 is formed, acceptor ions are implanted, and activated by heat processing. When the acceptor is boron, this heat processing is referred to as boron drive. As a heat processing time increases, the acceptor ions are diffused to a lower direction, and the CD/CS interface gets deeper.

Herein, the acceptor ions diffused near the trench 7 are taken in the oxide film 8. Thus, an acceptor ion concentration is low near the trench 7. In the meanwhile, donor ions in the CS layer are not taken in the oxide film 8. Accordingly, the CD/CS interface gets deeper with increasing distance from the sidewall of the trench and gets shallower near the trench 7, thus has resultingly the convex shape downward.

When the CS layer is the p type and the base layer is the n type by inverting the conductivity type, the CD/CS interface having a convex shape downward is obtained by the similar process.

While the embodiments etc. have been shown and described in detail, the above embodiments are not restrictive. Various modifications and replacements can be added to the above embodiments without departing from the scope of claims.

The aspects of the present disclosure are collectively described hereinafter as appendixes.

### Appendix 1

A semiconductor device, comprising:
a semiconductor substrate including a first main surface and a second main surface as a main surface on a side opposite to the first main surface;
a drift layer of a first conductivity type formed on the semiconductor substrate;
a carrier storage layer of a first conductivity type formed on a side of the first main surface of the drift layer;
a base layer of a second conductivity type formed on a side of the first main surface of the carrier storage layer;
a trench passing through the base layer and the carrier storage layer from the first main surface to reach the drift layer; and
a gate electrode buried in the trench via an oxide film, wherein
the gate electrode includes:
a lower stage gate electrode; and
an upper stage gate electrode formed closer to the side of the first main surface than the lower stage gate electrode,
in the carrier storage layer, an impurity concentration of a first conductivity type has a gauss distribution in a depth direction, and
a depth D1 of an interface between the base layer and the carrier storage layer near a sidewall of the trench satisfies D1≥(D2−1.0) [μm] with respect to a depth D2 of a deepest part of the upper stage gate electrode.

### Appendix 2

The semiconductor device according to Appendix 1, wherein
a depth D3 of a peak position of an impurity concentration of a first conductivity type in the carrier storage layer satisfies D3>D2 with respect to a depth D2 of a deepest part of the upper stage gate electrode.

### Appendix 3

The semiconductor device according to Appendix 1 or 2, wherein
the depth D1 of the interface between the base layer and the carrier storage layer near the sidewall of the trench satisfies D1<D2 with respect to the depth D2 of the deepest part of the upper stage gate electrode.

### Appendix 4

The semiconductor device according to any one of Appendixes 1 to 3, further comprising
a front surface electrode formed on the first main surface, wherein
the lower stage gate electrode has same potential as the front surface electrode, and
the upper stage gate electrode has potential different from the lower stage gate electrode.

### Appendix 5

The semiconductor device according to any one of Appendixes 1 to 4, wherein
an impurity concentration of a first conductivity type of the lower stage gate electrode is higher than an impurity concentration of a first conductivity type of the upper stage gate electrode.

### Appendix 6

The semiconductor device according to any one of Appendixes 1 to 5, wherein
the upper stage gate electrode includes:
an upper stage first part; and
an upper stage second part protruding to a side of the second main surface from a lower surface as a surface of the upper stage first part on a side of the second main surface, and
the upper stage first part and the upper stage second part form a concave shape toward the second main surface.

### Appendix 7

The semiconductor device according to Appendix 6, wherein
the lower stage gate electrode includes:
a lower stage first part; and
a lower stage second part protruding to a side of the first main surface from an upper surface as a surface of the lower stage first part on the side of the first main surface, and
the lower stage first part and the lower stage second part form a convex shape toward the first main surface.

### Appendix 8

The semiconductor device according to Appendix 7, wherein
an upper surface as a surface of the lower stage second part on the side of the first main surface is shallower than a lower surface as a surface of the upper stage second part on the side of the second main surface.

### Appendix 9

The semiconductor device according to Appendix 7 or 8, wherein
a width of the upper stage second part is smaller than a width of the lower stage first part.

### Appendix 10

The semiconductor device according to any one of Appendixes 1 to 9, wherein
the interface between the base layer and the carrier storage layer has a convex shape toward the second main surface.

While the disclosure has been shown and described in detail, the foregoing description is in all aspects illustrative and not restrictive. It is therefore understood that numerous modifications and variations can be devised.

What is claimed is:

1. A semiconductor device, comprising:
a semiconductor substrate including a first main surface and a second main surface as a main surface on a side opposite to the first main surface;
a drift layer of a first conductivity type formed on the semiconductor substrate;
a carrier storage layer of a first conductivity type formed on a side of the first main surface of the drift layer;
a base layer of a second conductivity type formed on a side of the first main surface of the carrier storage layer;
a trench passing through the base layer and the carrier storage layer from the first main surface to reach the drift layer; and
a gate electrode buried in the trench via an oxide film, wherein
the gate electrode includes:
a lower stage gate electrode; and
an upper stage gate electrode formed closer to the side of the first main surface than the lower stage gate electrode,
in the carrier storage layer, an impurity concentration of a first conductivity type has a gauss distribution in a depth direction, and
a depth D1 of an interface between the base layer and the carrier storage layer near a sidewall of the trench satisfies D1≥(D2−1.0) [μm] with respect to a depth D2 of a deepest part of the upper stage gate electrode.

2. The semiconductor device according to claim 1, wherein
a depth D3 of a peak position of an impurity concentration of a first conductivity type in the carrier storage layer satisfies D3>D2 with respect to a depth D2 of a deepest part of the upper stage gate electrode.

3. The semiconductor device according to claim 1, wherein
the depth D1 of the interface between the base layer and the carrier storage layer near the sidewall of the trench satisfies D1<D2 with respect to the depth D2 of the deepest part of the upper stage gate electrode.

4. The semiconductor device according to claim 1, further comprising
a front surface electrode formed on the first main surface, wherein
the lower stage gate electrode has same potential as the front surface electrode, and
the upper stage gate electrode has potential different from the lower stage gate electrode.

5. The semiconductor device according to claim 1, wherein
an impurity concentration of a first conductivity type of the lower stage gate electrode is higher than an impurity concentration of a first conductivity type of the upper stage gate electrode.

6. The semiconductor device according to claim 1, wherein
the upper stage gate electrode includes:
an upper stage first part; and
an upper stage second part protruding to a side of the second main surface from a lower surface as a surface of the upper stage first part on a side of the second main surface, and
the upper stage first part and the upper stage second part form a concave shape toward the second main surface.

7. The semiconductor device according to claim 6, wherein
the lower stage gate electrode includes:
a lower stage first part; and
a lower stage second part protruding to a side of the first main surface from an upper surface as a surface of the lower stage first part on the side of the first main surface, and
the lower stage first part and the lower stage second part form a convex shape toward the first main surface.

8. The semiconductor device according to claim 7, wherein
an upper surface as a surface of the lower stage second part on the side of the first main surface is shallower than a lower surface as a surface of the upper stage second part on the side of the second main surface.

9. The semiconductor device according to claim 7, wherein
a width of the upper stage second part is smaller than a width of the lower stage first part.

10. The semiconductor device according to claim 1, wherein
the interface between the base layer and the carrier storage layer has a convex shape toward the second main surface.
